(19) United States
(12) Patent Application Publication
(10) Pub. No.: US 2006/0261483 A1
(43) Pub. Date: Nov. 23, 2006

(54) Semiconductor device and method for manufacturing the same

(75) Inventors: Kazumichi Tsumura, Kawasaki-shi (JP); Naofumi Nakamura, Tokyo (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/248,608

(22) Filed: Oct. 13, 2005

(30) Foreign Application Priority Data
May 18, 2005 (JP) 2005-145575

(51) Int. Cl. H01L 23/52

(52) U.S. Cl. 257/758

(57) ABSTRACT

A semiconductor device and a method for manufacturing the same, in which degradation of performance of the interconnect structure caused by damage introduced to the low k interlevel insulator is suppressed, is disclosed. The semiconductor device comprises a low dielectric constant insulator formed with at least one of a wiring trench and contact hole therein and including a recovered layer in the vicinity of a surface of the wiring trench and/or contact hole by treating to make a carbon concentration and/or film density therein being equal to or higher than those in the inside of the insulator, a conductive layer formed in the wiring trench and/or contact hole, a barrier metal interposed between the low dielectric constant insulator and the conductive layer, and a second insulator interposed between the barrier metal and the low dielectric constant insulator.

### CROSS-REFERENCE TO RELATED APPLICATIONS

This application is based upon and claims the benefit of priority from prior Japanese Patent Application No. 2005-145575, filed May 18, 2005, the entire contents of which are incorporated herein by reference.

### BACKGROUND OF THE INVENTION

1. Field of the Invention

The present invention relates to a semiconductor device, and to a method for manufacturing the same. In particular, the present invention relates to a semiconductor device using a low dielectric constant insulator for an interlevel insulator, and to a method for manufacturing the same.

2. Description of the Related Art

As scale-down and high integration of semiconductor devices progress, a low dielectric constant (hereinafter, referred to as low k) insulator is widely employed as an interlevel insulator to suppress an increase in parasitic capacitance of interconnect and to achieve higher speed operation. In order to obtain such a low k insulator, for example, less than 2.5, a low density insulator has been developed. Namely, a porous low k insulator including very small pores therein is used as the interlevel insulator. However, following problems arise if it is desired to form a high performance and reliable multilevel interconnect structure using the porous low k insulator. For example, (1) the dielectric constant becomes smaller, the porosity of the interlevel insulator becomes higher. As a result, amount of water absorbed on the pore surface of the insulator increases, for this reason, H₂O gas is generated by heat in the manufacturing process or semiconductor device operation. (2) In forming wiring trenches (slit) and contact holes, the insulator receives plasma damage caused by, such as, reactive ion etching and plasma ashing.

The damage refers here to a state that a bond between atoms or molecules forming the low k insulator is broken. For example, in the case of a SiOCH-based low k film, as in general, Si—CH₃ bond or Si—C bond is broken due to active plasma thus forming Si-dangling bond or Si—OH. The foregoing portions receiving the damage are easy to absorb various gases, for example, moisture. For this reason, these portions emit absorbed gas when heat is applied in the manufacturing process or semiconductor device operation. In other words, the portions generate H₂O gas, for example.

If such a low k insulator is used as the interlevel insulator, copper wiring and/or barrier metal are oxidized, or corroded, by the generated H₂O gas, thereby adhesivity between barrier metal and wiring is degraded. As a result, an increase in resistance of contact plug and/or open in the interconnect structure could occur, therefore, there is a problem that performance and reliability of the interconnect structure are degraded.

Besides, the following have been known as typical problems of the porous low k insulator, such as, reduction in adhesivity between the low k insulator and silicon oxide film (SiO₂ film), peeling of the SiO₂ film, corrosion of wiring materials, and diffusion of barrier metal elements to the low k insulator, and the like.

JPN. PAT. APPLN. KOKAI Publication No. 2004-207604 discloses a technique for improving degradation of adhesivity between the low k insulator and the SiO₂ film resulting from internal stress therebetween. According to the technique, a buffer layer is interposed between the low k insulator and the SiO₂ film to improve adhesivity. The buffer layer has carbon concentration lower than that of the low k insulator, and contains no nitrogen. The buffer layer is formed by modifying the surface layer of the low k insulator treated under helium or argon gas plasma. The plasma treatment is carried out to the low k insulator surface before contact holes and wiring trenches are formed. Thus, the treatment does not contribute for preventing corrosion of a barrier metal formed inside of the contact hole and wiring trench.

JPN. PAT. APPLN. KOKAI Publication No. 2002-353308 discloses a technique of recovering damage introduced to the low k insulator by patterning, such as dry etching. According to the technique, the damage is cased by dissociation of methyl-base or carbon from the low k insulator. A treatment, which makes a surface hydrophobic or soluble, is carried out to the damaged surface layer to recover or remove it. However, the treatment is not sufficient enough to prevent corrosion of barrier metal and wiring material.

A technique of covering the surface of porous low k insulator with another insulator is published by C. Guedj et. al., in “Effect of pore sealing on the reliability of ULK/Cu interconnects”, in Proc. IITC 2004, pp. 148-150. If wiring metal diffuses into the low k insulator, the dielectric constant of the low k insulator increases. According to the technique, after forming contact hole and wiring trench, the surface of the low k insulator is covered with a SiC:H sealing film. The sealing film has a function of preventing metal from diffusing into the low k insulator. Therefore, it can be prevented the low k insulator from deteriorating by the metal diffusion, thus improving the reliability of the interconnect structure. However, the technique does not describe about recovery of damage introduced to the low k insulator and diffusion of moisture absorbed in the damaged layer to the barrier metal.

Therefore, there is a need to provide a semiconductor device, which can suppress degradation of performance of the interconnect structure caused by damage introduced to the low k interlevel insulator, and a method for manufacturing the same.

### BRIEF SUMMARY OF THE INVENTION

According to one aspect of the present invention, it is provided a semiconductor device comprising: a low dielectric constant insulator formed with at least one of a wiring trench and contact hole therein and including a recovered layer in the vicinity of a surface of the wiring trench and/or contact hole by treating to make a carbon concentration and/or film density therein being equal to or higher than those in the inside of the insulator; a conductive layer formed in the wiring trench and/or contact hole; a barrier metal interposed between the low dielectric constant insulator and the conductive layer; and a second insulator interposed between the barrier metal and the low dielectric constant insulator.

According to another aspect of the present invention, it is provided a semiconductor device comprising: a first insulator formed above a semiconductor substrate; a first wiring formed in the first insulator; a second wiring formed above the first wiring; a contact plug connecting the first and second wirings; a second insulator formed around at least one of the second wiring and contact plug and including a recovered layer formed in the vicinity of an interface between the second insulator and the second wiring or contact plug, wherein the recovered layer is treated to make a carbon concentration and/or film density therein being equal to or higher than those in the inside of the second insulator; a barrier metal interposed between the second insulator and the second wiring or contact plug; and a third insulator interposed between the barrier metal and the second insulator.

According to still another aspect of the present invention, it is provided a method for manufacturing a semiconductor device, comprising: depositing a first insulator above a semiconductor substrate; forming at least one of a wiring trench and contact hole in the first insulator; recovering damage introduced to the first insulator in the vicinity of the surface of the wiring trench and/or contact hole; forming a second insulator on a surface of the wiring trench and/or contact hole; forming a barrier metal on the second insulator; and forming a conductive layer in at least one of the wiring trench and contact hole.

### BRIEF DESCRIPTION OF THE SEVERAL VIEWS OF THE DRAWING

FIG. 1 is a cross-sectional view to explain an example of a semiconductor device according to a first embodiment of the present invention;

FIGS. 2A, 2B, 2C, 2D, 2E and 2F are cross-sectional views to explain an example of a process of manufacturing the semiconductor device according to the first embodiment of the present invention;

FIGS. 3A, 3B and 3C are cross-sectional views to explain an example of a process of manufacturing a semiconductor device according to a second embodiment of the present invention;

FIGS. 4A, 4B, 4C and 4D are cross-sectional views to explain an example of a process of manufacturing a semiconductor device according to a third embodiment of the present invention;

FIGS. 5A, 5B, 5C and 5D are cross-sectional views to explain an example of a process of manufacturing a semiconductor device according to a fourth embodiment of the present invention;

FIG. 6 is a cross-sectional view to explain a semiconductor device according to a first modification of the present invention;

FIG. 7 is a cross-sectional view to explain a semiconductor device according to a second modification of the present invention; and

FIG. 8 is a graph to explain a relation between a rate of resistivity increase of a contact plug and a diameter of a contact hole.

### DETAILED DESCRIPTION OF THE INVENTION

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

The present invention relates to a semiconductor device using a low k insulator as an interlevel insulator, and to a method for manufacturing the same. The semiconductor device comprises: recovering damage introduced by plasma processing to a processed surface and its vicinity of the interlevel insulator in a process of forming a wiring trench and/or contact hole in the interlevel insulator; and forming an insulator for suppressing diffusion of moisture, oxygen, and the like between the interlevel insulator and a barrier metal.

According to the present invention, as damage in the interlevel insulator particularly around the contact hole is recovered, it can be suppressed adsorption of moisture to the damaged layer. Therefore, it can be prevented desorption of gaseous component absorbed in the interlevel insulator, e.g., generation of H₂O gas, resulting from heat applied during subsequent manufacturing process and/or operation of the semiconductor device. In addition, even if the H₂O gas is generated from the interlevel insulator, diffusion of the H₂O gas to the barrier metal is prevented by the moisture barrier insulator interposed between the interlevel insulator and barrier metal. As a result, oxidation of the barrier metal is prevented. Moreover, the adhesivity between the barrier metal and the interlevel insulator is improved since a rough surface of the porous insulator in which wiring trench and/or contact hole is formed is covered with the moisture barrier insulator and thereby smoothened. As described above, since the generation of the H₂O gas is prevented, it can be suppressed a degradation of the performance and reliability of the interconnect structure due to resistivity increase of contact plug and the like. Therefore, the moisture barrier insulator between the interlevel insulator and barrier metal can be formed thinner as compared with the case where H₂O gas is generated more because of the damage remained in the interlevel insulator. This is effective to the miniaturization of the semiconductor device, because the diameter of the contact plug becomes smaller, the resistivity increase of the contact plug and degradation of the performance of the interconnect structure are suppressed more effectively.

The present invention will be described below in detail with referring to some embodiments thereof.

### First Embodiment

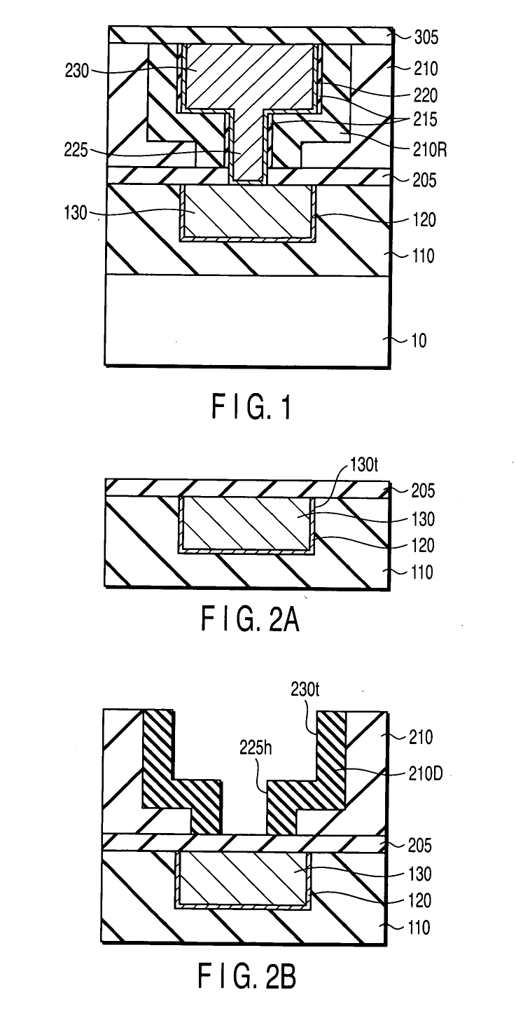

FIG. 1 shows an example of a sectional structure of a semiconductor device according to a first embodiment of the present invention. The first embodiment relates to a semiconductor device comprising: a second interlevel insulator 210 formed above a semiconductor substrate 10; a recovered layer 210R in which damages introduced to the etched surface of wiring trench and contact hole during their formation are recovered by using an organic material; and a contact plug 225 and a second wiring 230 formed on the recovered layer 210R through a second insulator 215 and second barrier metal 220, and to a method for manufacturing the same.

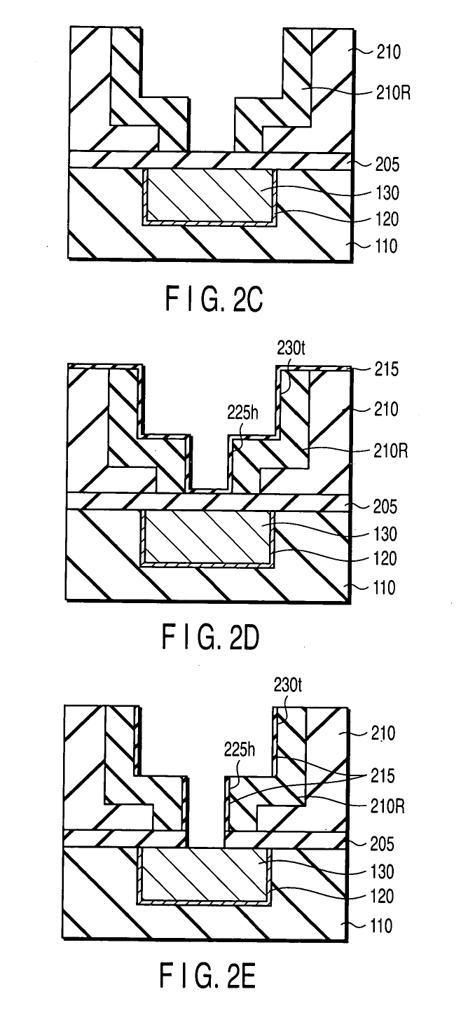

An example of a manufacturing process the semiconductor device according to the first embodiment will be explained below with reference to cross-sectional views shown in FIG. 2A to FIG. 2F. In the following FIG. 2A to FIG. 2F, the semiconductor substrate is omitted, and an interconnect structure which is directly related to the present invention is only illustrated therein.

(1) First, isolation (not shown) and MOSFET (not shown) are formed on a semiconductor substrate (not shown). Referring now to FIG. 2A, a first insulator 110 is deposited on an entire surface over the MOSFET. Thereafter, the surface is planarized using chemical mechanical polishing (CMP), for example. The first insulator 110 is preferably a low k insulator having a dielectric constant of 2.5 or less. It can be used, for example, an organic silicon film such as methyl siloxane film containing siloxane, e.g., SiOC, SiOCH, an organic film such as polyallylene ether, or a porous film making those films porous. A first wiring trench 130t is formed in the first insulator 110, and thereafter, a first barrier metal 120 is formed on the inner wall of the first wiring trench 130t. The first barrier metal 120 is a conductive film to prevent a wiring material from diffusing outside. For example, tantalum (Ta), tantalum nitride (TaN), or titanium nitride (TiN) can be used. Then, copper (Cu) is deposited in the first wiring trench 130t via a seed layer (made of Cu, not shown) using, for example, electroplating, thus forming a first wiring 130. For example, a low resistance metal such as Cu alloy can be used as a wiring metal in addition to Cu. A first diffusion preventing film 205 is formed on an entire surface of the first insulator 110 including on the first wiring 130. As the first diffusion preventing film 205, an insulator capable of preventing diffusion of Cu, for example, a silicon nitride (SiN) film, can be used.

In this way, the first wiring 130 is formed in the first insulator 110 as shown in FIG. 2A.

(2) As illustrated in FIG. 2B, a second interlevel insulator 210 is deposited on an entire surface of the first diffusion preventing film 205. The second interlevel insulator 210 is preferably a low k insulator having a dielectric constant of 2.5 or less, like the first insulator 110. A contact hole 225h and second wiring trench 230t for dual damascene are formed in the second interlevel insulator 210 by lithography and etching. During the above processing, damage is introduced by plasma used in the etching and/or resist removal ashing in the vicinity of the surface of the processed contact hole 225h and second wiring trench 230t formed in the second interlevel insulator 210. If the methyl siloxane film is used as the second interlevel insulator 210, the damage refers here, for example, reduction in carbon concentration of the film, breakage of bond of element constituting the insulator, or the like, due to dissociation of methyl group from the vicinity of the etched surface of the insulator. Thus, damaged layer 210D having a lower carbon concentration and lower film density is created in the vicinity of the etched surface of the second interlevel insulator 210. The damaged layer 210D is easy to absorb moisture or atmospheric gas.

(3) The damage in the second interlevel insulator 210 is recovered before removing the first diffusion preventing film 205 on the first wiring 130 at the bottom of the contact hole. Namely, an organic material is supplied to the etched surface with liquid or gas phase. Then heat is applied to cause the organic material to react with the damaged layer 210D and to supply carbon to the damaged layer 210D. Specifically, the etched surface is heated to a temperature from 150° C. to 350° C. in an atmosphere containing the organic material, for example, hexamethyl disilazane (HMDS). In this way, as shown in FIG. 2C, the damaged layer 210D is modified into a recovered layer 210R, where a carbon concentration and/or film density of the etched surface of the second interlevel insulator 210 are equivalent to or more than those in the bulk. The carbon concentration of the surface of the recovered layer 210R is 5 atomic % or more at a position of 15 nm inside from the surface, for example.

(4) As depicted in FIG. 2D, a second insulator 215 is formed, for example, chemical vapor deposition (CVD) over an entire surface including contact hole 225h and second wiring trench 230t where the damages are recovered. The second insulator 215 is a moisture barrier film having a function to prevent diffusion of moisture or oxygen from the second interlevel insulator 210 to a barrier metal 220 being formed thereon later. Moreover, the second insulator 215 has another effect of smoothing the surface of the porous second interlevel insulator 210 having a rough surface to improve the adhesivity with the barrier metal being formed. The second insulator 215 is also preferably a film having a low dielectric constant. For example, an insulator containing at least one of carbon and nitrogen, such as organic SiC or SiCN, can be used. If the film density becomes higher, the dielectric constant also increases, therefore an insulator having a film density of 2 g/cm³ or less and low k can be used. The insulator has a relatively low dielectric constant and properties hard to pass moisture therethrough. By using such a low k insulator, it can be suppressed an increase of interconnect capacitance as well as achieving the effect of the present invention.

The second insulator 215 is set to a thickness so that a rate of resistivity increase of contact plug is 20% or less, although the detail will be described later. Thereby, it can be prevented the degradation of characteristics of the semiconductor device caused by the resistivity increase in the interconnect structure. Here, the rate of resistivity increase is defined as a resistance ratio of contact plug between with and without forming the second insulator 215 in the contact hole.

(5) As shown in FIG. 2E, the second insulator 215 and the first diffusion preventing film 205 at the bottom of the contact hole 225h are removed using anisotropic etching to expose the first wiring 130. In this process, the second insulator 215 deposited on the bottom of the second wiring trench 230t and the surface of the second interlevel insulator 210 are simultaneously removed. As a result, the exposed surface of the second interlevel insulator 210 receives damage. However, both the second insulator 215 and first diffusion preventing film 205 are thin, therefore, the received damage is also small. On the other hand, during the etching, a side face of the contact hole 225h which is most sensitive to the damage is covered with the second insulator 215, therefore, no damage is introduced therein.

(6) As shown in FIG. 2F, a second wiring 230 is formed. Here, the second wiring 230 is formed in a similar manner to the first wiring 130 described in the foregoing process (1). Specifically, a second barrier metal 220 is formed on an entire surface including the inner surface of contact hole 225 and second wiring trench 230t. Then, Cu is deposited via a Cu seed layer (not shown) using electroplating, for example. Thereafter, the second barrier metal 220 and Cu formed on the surface of the second interlevel insulator 210 are removed using CMP while being planarized, and thereby, the contact plug 225 and the second wiring 230 are formed.

The process for forming the wirings described above is repeated to form a desired multilevel interconnect structure, and then, processes required for semiconductor devices are carried out. In this way, a semiconductor device in which the reliability of the interconnect structure is improved is completed.

The present invention is not limited to the embodiment described above, and various modifications can be made. For example, the interlevel insulator is divided into two layers, one for forming the contact plug and the other for forming the wiring, and different material can be used for the individual layers.

In the first embodiment, various processes can be used for forming the contact hole 225h and the second wiring trench 230t. One example is a process of etching the contact hole in advance. Another example is a hard mask process of simultaneously forming wiring trench and contact hole using a hard mask. Thus, the first embodiment can be applied without depending on the type of the process used.

According to the first embodiment, there is provided a semiconductor device and a method for manufacturing the same, in which damage introduced by plasma processing to a low k interlevel insulator is recovered and degradation of the performance of the interconnect structure resulting from the damage is prevented.

### Second Embodiment

The second embodiment of the present invention relates to a semiconductor device comprising features that a first diffusion preventing film 205 on a first wiring 130 at the bottom of a contact hole 225h is removed first, then damage introduced to a second interlevel insulator 210 during its etching is recovered. Thereby, the reliability of contact plug and wiring is improved. According to the second embodiment, damage introduced to the bottom of the second wiring trench 230t is further reduced as compared with the first embodiment.

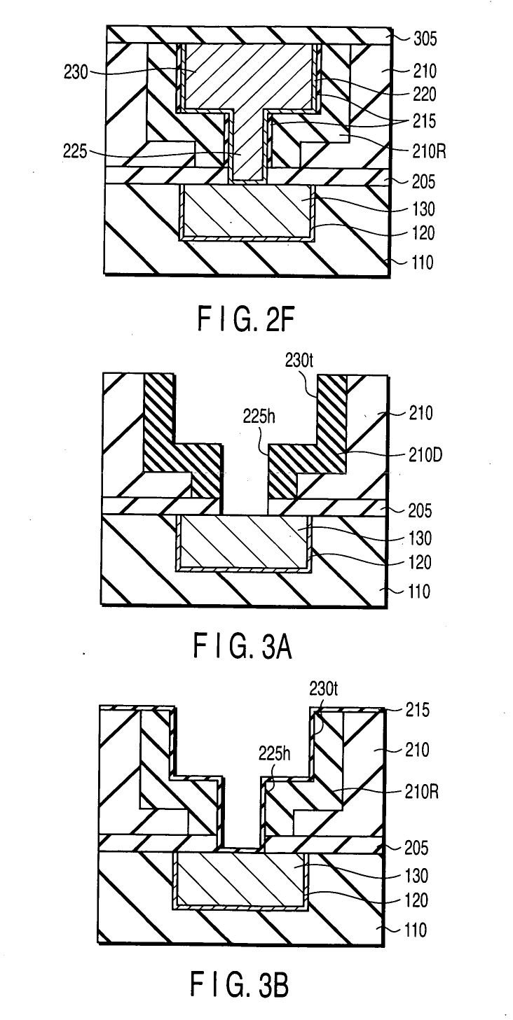

The manufacturing process of the semiconductor device according to the second embodiment will be explained below with reference to cross-sectional views shown in FIG. 3A to FIG. 3C.

(1) As shown in FIG. 3A, a first wiring 130 is formed in a first insulator 110. A first diffusion preventing film 205 and second interlevel insulator 210 are formed on the surface of the first insulator 110 and first wiring 130. Then a contact hole 225h and second wiring trench 230t are formed in the second interlevel insulator 210 by lithography and etching. The first diffusion preventing film 205 at the bottom of the contact hole 225h is selectively etched to expose the surface of the first wiring 130. During the etching, damage is introduced to the second interlevel insulator 210 in the vicinity of the surface of the contact hole 225h and the second wiring trench 230t. As a result, a damaged layer 210D is formed therein. In the damaged layer 210D, a carbon concentration and/or film density are smaller than those in the bulk.

(2) As illustrated in FIG. 3B, damage recovery treatment is carried out to the damaged layer 210D. The damage recovery treatment is carried out in the same manner as in the process (3) of the first embodiment. Specifically, an organic material is supplied to the etched surface in liquid or gas phase and heated to cause reaction. In this way, carbon is supplied to the damaged layer 210D in the second interlevel insulator 210 in the vicinity of the etched surface. Thus, as described above, the damaged layer 210D is modified into a recovered layer 210R in which a carbon concentration and/or film density are equal to or more than those in the bulk.

(3) Then, a second insulator 215 is formed on an entire surface including inner surface of the contact hole 225 and second wiring trench 230t. The second insulator 215 is, for example, an insulator containing at least one of carbon and nitrogen, such as organic SiC or SiCN. The second insulator 215 is a moisture barrier insulator and has a function to prevent from diffusing moisture and/or oxygen to a barrier metal and wiring to be formed from the second interlevel insulator 210.

The second insulator 215 formed on the bottom of the contact hole 225h is removed using anisotropic etching. Then, the inner surfaces of the contact hole 225h and second wiring trench 230t are covered with a second barrier metal 220. Thereafter, the contact hole 225h and second wiring trench 230t are filled with wiring metal, and then, the surface is planarized to form a contact plug 225 and second wiring 230. A second diffusion preventing film 305 is formed on an entire surface of the second interlevel insulator 210 including the surface of the second wiring 230, thereby, the structure shown in FIG. 3C is completed.

The process of forming the wirings described above is repeated to form a desired multilevel interconnect structure, and then, processes required for semiconductor devices are carried out. In this manner, a semiconductor device in which the reliability of the interconnect structure is improved is completed.

According to the second embodiment, the number of processes increases as compared with the first embodiment because etching to the bottom of the contact hole 225h is divided into two steps; one is etching for the second diffusion preventing film 205, and another is etching for the second insulator 215. However, in the process after recovering the damaged layer 210D, plasma damage introduced to the second interlevel insulator 210 at the bottom of the second wiring trench 230t is reduced. In other words, the plasma damage is reduced because a shorter etching time is applied to etch the thin second insulator 215. Therefore, the damage introduced to the second interlevel insulator 210 is reduced as compared with the first embodiment. Therefore, moisture absorbed in the second interlevel insulator 210 is reduced and thus outgas therefrom is also reduced.

According to the second embodiment, there is provided a semiconductor device and a method for manufacturing the same, in which damage introduced by plasma processing to a low k interlevel insulator is recovered and degradation of the performance of the interconnect structure resulting from the damage is prevented.

### Third Embodiment

The third embodiment of the present invention relates to a semiconductor device and a method for manufacturing the same, in which damage introduced in the vicinity of a contact hole is recovered. A contact plug is one of the most damage sensitive portion where the degradation in the reliability of the interconnect structure is easy to occur. Here, only contact hole is first formed in a low k interlevel insulator, and then, a wiring trench is formed after damaged layer in the interlevel insulator around the contact hole is recovered.

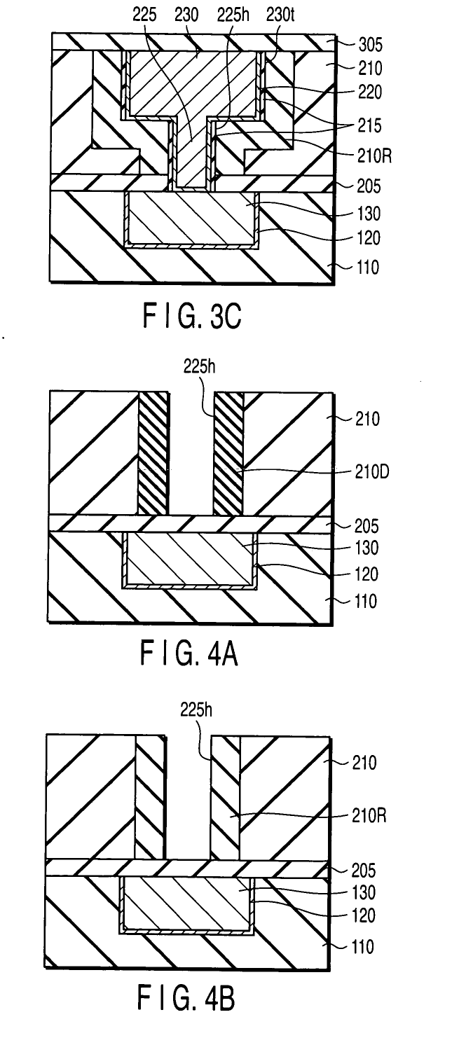

The process of manufacturing the semiconductor device according to the third embodiment will be described below with reference to sectional views shown in FIG. 4A to FIG. 4D.

(1) As shown in FIG. 4A, a first wiring 130 is formed in a first insulator 110. Then, a first diffusion preventing film 205 and second interlevel insulator 210 are formed on the surface of the first insulator 110 and first wiring 130. A contact hole 225h is formed in the second interlevel insulator 210 by lithography and etching. During the processing, damage is introduced to the second interlevel insulator 210 in the vicinity of the surface of the contact hole 225h. As a result, a damaged layer 210D is formed therein. In the damaged layer 210D, a carbon concentration and/or film density are smaller than those in the bulk.

(2) As illustrated in FIG. 4B, damage recovery treatment is carried out to the damaged layer 210D. The damage recovery treatment is carried out in the same manner as in the process (3) of the first embodiment. Specifically, an organic material is supplied to the etched surface in liquid or gas phase and heated to cause reaction. In this way, carbon is supplied to the damaged layer 210D in the second interlevel insulator 210 in the vicinity of the etched surface. Thus, as described above, the damaged layer 210D is modified into a recovered layer 210R in which a carbon concentration and/or film density are equal to or more than those in the bulk.

(3) As depicted in FIG. 4C, a second insulator 215 is formed on an entire surface including inner surface of the contact hole 225 and second wiring trench 230t. The second insulator 215 is, for example, an insulator containing at least one of carbon and nitrogen, such as organic SiC or SiCN. The second insulator 215 is a moisture barrier insulator and has a function to prevent from diffusing moisture or oxygen to a barrier metal and wiring being formed from the second interlevel insulator 21.

The contact hole 225h is further filled with an organic insulator 228, for example, resist. Then, a second wiring trench 230t is formed in the second interlevel insulator 210 by lithography and etching. During the processing, the surface of the contact hole 225h receives no damage because of being covered with the organic insulator 228 and second insulator 215.

The organic insulator 228 is removed, and thereafter, the process after the process (5) of the first embodiment is carried out, and thereby, the interconnect structure shown in FIG. 4D is completed. Specifically, the second insulator 215 and the first diffusion preventing film 205 at the bottom of the contact hole 225h are removed by anisotropic etching. Then, a second barrier metal 220 and wiring material (Cu) are formed in the contact hole 225h and second wiring trench 230t. In this way, the interconnect structure shown in FIG. 4D is completed.

According to the third embodiment, the second insulator 215 is left only on the side face of the contact plug 225.

The process of forming the wirings described above is repeated to form a desired multilevel interconnect structure, and then, processes required for semiconductor devices are carried out. In this manner, a semiconductor device in which the reliability of the interconnect structure is improved is completed.

According to the third embodiment, the second interlevel insulator 210 at the side of the contact hole 225h is the recovered layer 210R in which damage is recovered. However, the side and bottom surfaces of the second wiring trench 230t does not receive damage recovery treatment.

According to the third embodiment, the first diffusion preventing film 205 at the bottom of the contact hole 225h is removed after the damaged layer 210D in the vicinity of the surface of the contact hole 225h is recovered. However, as in the second embodiment, the process can be variously modified, for example, removing the first diffusion preventing film 205 at the bottom of the contact hole 225h first, then being carried out damage recovery treatment.

According to the third embodiment there is provided a semiconductor device and a method for manufacturing the same, in which damage introduced by plasma processing to a low k interlevel insulator is recovered and degradation of the performance of the interconnect structure resulting from the damage is prevented.

### Fourth Embodiment

The fourth embodiment of the present invention relates to a semiconductor device and a method for manufacturing the same, in which damage recovery treatment is carried out to the most damage sensitive portion, i.e., in the vicinity of a contact hole, like the third embodiment. In the embodiment, a second insulator having a function of preventing diffusion of moisture is formed after a wiring trench is formed.

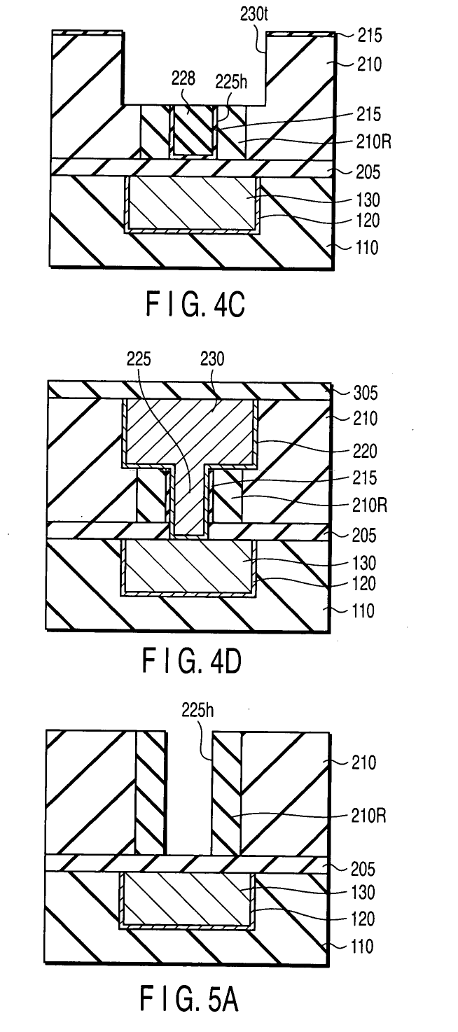

The process of manufacturing the semiconductor device according to the fourth embodiment will be described below with reference to sectional views shown in FIG. 5A to FIG. 5D.

(1) FIG. 5A is similar to FIG. 4B. As shown in FIG. 5A, a first wiring 130 is formed in a first insulator 110. Then, a first diffusion preventing film 205 and second interlevel insulator 210 are formed on the surface of the first insulator 110 and first wiring 130. A contact hole 225h is formed in the second interlevel insulator 210 by lithography and etching. During the processing, damage is introduced to the second interlevel insulator 210 in the vicinity of the surface of the contact hole 225h. As a result, damaged layer 210D is formed in the second interlevel insulator 210.

Damage recovery treatment is carried out to the damaged layer 210D. The damage recovery treatment is carried out in the same manner as in the process (3) of the first embodiment. Specifically, an organic material is supplied to the etched surface in liquid or gas phase and heated to cause reaction. In this way, carbon is supplied to the damaged layer 210D in the second interlevel insulator 210 in the vicinity of the etched surface. Thus, as described above, the damaged layer 210D is modified into a recovered layer 210R in which a carbon concentration and/or film density are equal to or more than those in the bulk.

(2) As depicted in FIG. 5B, a second wiring trench 230t is formed. Specifically, the contact hole 225h is filled with an organic insulator 228, for example, resist. Then, a second wiring trench 230t is formed in the second interlevel insulator 210 by lithography and etching. In the processing, the inner surface of the contact hole 225h does not receive damage since the contact hole 225h is filled with the organic insulator 228.

(3) The organic insulator 228 in the contact hole 225h is removed. Thereafter, as depicted in FIG. 5C, a second insulator 215 is formed on an entire surface including the inner surfaces of the contact hole 225 and the second wiring trench 230t. The second insulator 215 is, for example, an insulator containing at least one of carbon and nitrogen, such as organic SiC or SiCN formed by CVD. The second insulator 215 is a moisture barrier insulator and has a function to prevent from diffusing moisture or oxygen to a barrier metal and wiring from the second interlevel insulator 210.

Thereafter, the process after the process (5) of the first embodiment is carried out, and thereby, the interconnect structure shown in FIG. 5D is completed. Specifically, the second insulator 215 and the first diffusion preventing film 205 at the bottom of the contact hole 225h are removed by anisotropic etching. Then, a second barrier metal 220 and wiring material (Cu) are formed in the contact hole 225h and second wiring trench 230t. In this way, the interconnect structure shown in FIG. 5D is completed.

The process of forming the wirings described above is repeated to form a desired multilevel interconnect structure, and then, processes required for semiconductor devices are carried out. In this manner, a semiconductor device improving the reliability of the interconnect structure is completed.

According to the fourth embodiment, as in the third embodiment, the second interlevel insulator 210 at the side of the contact hole 225h is the recovered layer 210R in which damage is recovered. However, the side and bottom surfaces of the second wiring trench 230t does not receive damage recovery treatment.

According to the fourth embodiment, the first diffusion preventing film 205 at the bottom of the contact hole 225h is removed after the damaged layer 210D in the vicinity of the surface of the contact hole 225h is recovered. However, as in the second embodiment, the process can be variously modified, for example, removing the first diffusion preventing film 205 at the bottom of the contact hole 225h first, then being carried out damage recovery treatment.

According to the fourth embodiment, there is provided a semiconductor device and a method for manufacturing the same, in which damage introduced by plasma processing to a low k interlevel insulator is recovered and degradation of the performance of the interconnect structure resulting from the damage is prevented.

The present invention is not limited to the foregoing embodiments, and various modifications can be implemented. Some modifications are described below.

### First Modification

The above embodiments are described to the structure of forming the diffusion preventing insulator film on the entire surface of the insulator being formed the wiring therein. The present invention can be applied to a structure in which the diffusion preventing conductive film is formed only on the upper surface of the wiring metal. In other words, the present invention can be applied to a so-called cap metal or top barrier metal structure (hereinafter, referred to as cap metal structure).

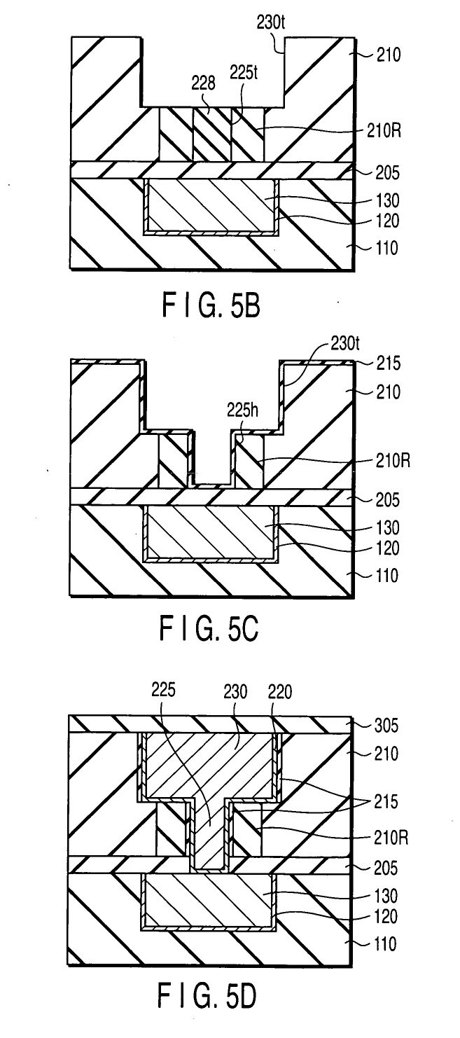

A first modification of the present invention can be applied to various structures including the first to fourth embodiments, in which the diffusion preventing film is formed on an entire surface of the interlevel insulator and the lower-level wiring formed therein. An example of the first modification is shown FIG. 6, in which the first embodiment is modified. FIG. 6 is a cross-sectional view to explain the interconnect structure of a semiconductor device according to the first modification.

In the present modification, the first and second diffusion preventing films 205 and 305 on the first and second insulators 110 and 210 are deleted from the interconnect structure of the first embodiment shown in FIG. 1, and first and second cap metals 135 and 235 are formed only on metal wirings 130 and 230. Similar to the barrier metal, Ta, TaN or TiN may be used as the cap metal. In addition, a film containing a metal with a high melting point, for example, cobalt tungsten (CoW) can be used. The film is preferable because being selectively formed only on Cu wiring using selective plating. For example, cobalt tungsten boride (CoWB) or cobalt tungsten phosphide (CoWP) can be used as the high melting point metal film containing CoW. The cap metals 135 and 235 have no need to be removed from the bottom of the contact hole 225 because they are conductive. Therefore, after the damaged layer 210D in the second interlevel insulator 210 in the vicinity of the contact hole 225h and the second wiring trench 230t is recovered, only second insulator 215 at the bottom of the contact hole 225h is removed before barrier metal and wiring metal are deposited. Therefore, less damage is introduced to the bottom of the second wiring trench 230t as compared with the first embodiment. As a result, moisture absorbed in the interlevel insulator is reduced. Moreover, it can be reduced gas desorption from the interlevel insulator by heat treatment after forming the wirings or by a rise of temperature in the operation of the semiconductor device.

According to the first modification, there is provided a semiconductor device and a method for manufacturing the same, in which damage introduced by plasma processing to a low k interlevel insulator is recovered and degradation of the performance of the interconnect structure resulting from the damage is prevented.

### Second Modification

The embodiments and modification described above have explained related to the dual damascene structure in which contact hole and wiring trench formed in the interlevel insulator are simultaneously filled with a barrier metal and wiring metal. The present invention can be applied to a single damascene structure in which contact hole and wiring trench are separately filled with the barrier metal and wiring metal in the processes separate from each other.

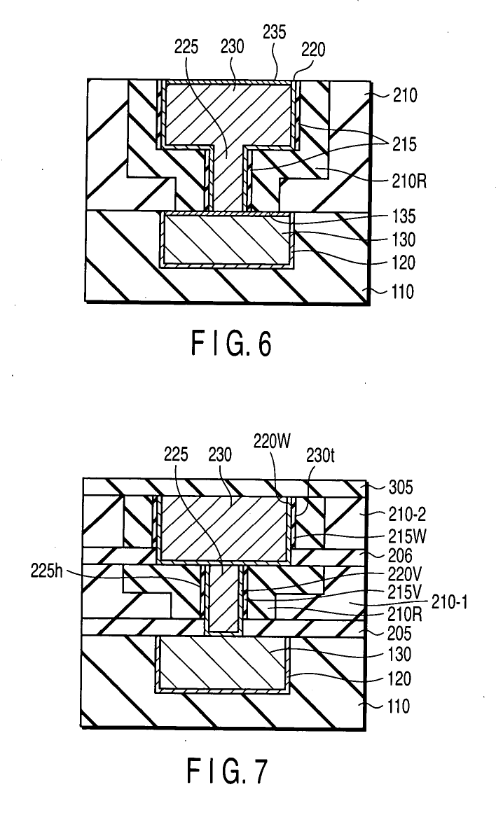

An example of a semiconductor device having a single damascene structure according to a second modification of the present invention is shown in FIG. 7. FIG. 7 is a cross-sectional view to explain a interconnect structure of a semiconductor device according to the modification.

According to the second modification, a contact hole 225h and second wiring trench 230t are individually formed. In the modification, an additional diffusion preventing film 206 is disposed between two layered second interlevel insulators 210-1, 210-2. Damage recovery treatments are separately carried out to each of the contact hole 225h and second wiring trench 230t. After the damage recovery, each of the etched surfaces is covered with each of second insulators 215V or 215W preventing moisture from diffusing. Thus, these serve to reduce damage introduced to the side of contact hole 225h and the side and bottom of the second wiring trench 230t in the later processes. As a result, moisture absorbed in the interlevel insulator is reduced. Therefore, it can be reduced gas desorption from the interlevel insulator by heat treatment after forming the wirings or by a rise of temperature in the operation of the semiconductor device.

According to the present invention, a carbon concentration of the damaged layer 210D of the low k interlevel insulator 210 is modified equal to or more than that in the bulk by the damage recovery treatment. Thereby, the surface of the low k interlevel insulator 210 is modified into a recovered layer 210R having less moisture adsorption site. As a result, the moisture adsorption property of the low k interlevel insulator 210 is improved. Moreover, since the insulator 215 is interposed between the low k interlevel insulator 210 and the barrier metal 220, diffusion of H₂O gas from the interlevel insulator 210 to the barrier metal 220 is prevented. Therefore, oxidization of the barrier metal is reduced, and thus degradation in the performance and reliability of the interconnect structure is prevented.

Moreover, a thickness of the second insulator (the moisture barrier film) 215 formed between interlevel insulator 210 and the barrier metal 220 can be thinned as compared with a case in which the damaged layer 210D is remained in the interlevel insulator 210 without carrying out damage recovery treatment and more gas may be generated. As a result, it can be reduced a rise of resistivity in the contact plug and thus providing an interconnect structure suitable for scale-down.

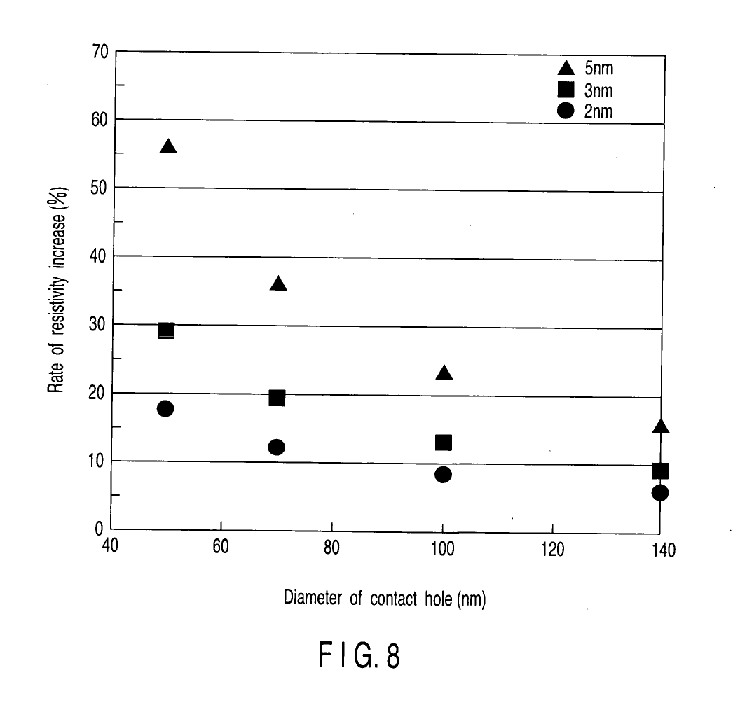

FIG. 8 is a graph to explain a rate of resistivity increase of contact plug as a function of contact hole diameter by thickness of the moisture barrier insulator. In the graph of FIG. 8, the horizontal axis shows a diameter of contact hole, and the vertical axis shows a rate of resistivity increase of contact plug. The rate of resistivity increase of contact plug is a rate of resistivity increase in one case against another case given below. One is a case where the moisture barrier insulator is formed in a contact hole with a certain diameter. Another is a case where a moisture barrier insulator is not formed in a contact hole having the same diameter. In FIG. 8, a circle shows the case where the thickness of the moisture barrier insulator is 2 nm. A square shows the case where the thickness is 3 nm, and a triangle shows the case where the thickness is 5 nm. If the diameter of contact hole is smaller, an influence of the insulator thickness to the resistivity increase is larger as shown in the FIG. 8. When the diameter of contact hole is 70 nm, an allowable thickness of the moisture barrier insulator is less than 3 nm, because an allowable rate of resistivity increase of contact plug is 20%, as described above. When the diameter of contact hole is 50 nm, an allowable thickness of the insulator becomes smaller and is less than about 2 nm.

It is required to the moisture barrier insulator not to permeate moisture through it as well as to have a low dielectric constant because it substantially acts as a part of the interlevel insulator. In general, an insulator with a higher moisture barrier capability has a high film density. However, a film with a higher density has a higher dielectric constant. For this reason, it is preferred to use an insulator containing carbon and/or nitrogen making film density lower than that of SiO₂ (e.g., film density of 2 g/cc or less), and having a higher moisture barrier capability, for example, SiC or SiCN can be used. Using such material, the dielectric constant can be made low, and the capacitance between the wirings can be suppressed, thus, the effect of the present invention is achieved.

Moreover, the surface of the porous interlevel insulator is smoothened by covering the surface of contact hole and wiring trench with the moisture barrier insulator. Thereby, it can be improved adhesivity of the barrier metal formed on the surface of the moisture barrier insulator.

In general, siloxane-containing materials, such as SiOC, SiOCH, and organic polymer are used as the low k interlevel insulator having a dielectric constant of 2.5 or less. A siloxane-based low k insulator has properties to be easily damaged in processing such as etching. An organic polymer material has low k and low film density, however, it is porous and has a high porosity. When the low k insulator is used as the interlevel insulator, the effect of the present invention remarkably appears.

According to the present invention, there is provided a semiconductor device and a method for manufacturing the same, in which damage introduced by plasma processing to a low k interlevel insulator is recovered and degradation of the performance of the interconnect structure caused by the damage is suppressed.

Additional advantages and modifications will readily occur to those skilled in the art. Therefore, the invention in its broader aspects is not limited to the specific details and representative embodiments shown and described herein. Accordingly, various modifications can be made without departing from the spirit or scope of the general inventive concept as defined by the appended claims and their equivalents.

What is claimed is:

1. A semiconductor device comprising:
a low dielectric constant insulator formed with at least one of a wiring trench and contact hole therein and including a recovered layer in the vicinity of a surface of the wiring trench and/or contact hole by treating to make a carbon concentration and/or film density therein being equal to or higher than those in the inside of the insulator;
a conductive layer formed in the wiring trench and/or contact hole;
a barrier metal interposed between the low dielectric constant insulator and the conductive layer; and
a second insulator interposed between the barrier metal and the low dielectric constant insulator.

2. The device according to claim 1, wherein the low dielectric constant insulator has a dielectric constant of 2.5 or less.

3. The device according to claim 1, wherein the second insulator contains silicon and at least one of carbon and nitrogen.

4. The device according to claim 1, wherein a surface of the second insulator is smoother than a surface of the low dielectric constant insulator contacting.

5. The device according to claim 1, wherein a rate of resistivity increase of the conductive layer formed in the contact hole with the second insulator is less than 20% compared with the resistivity of the conductive layer without the second insulator.

6. The device according to claim 1, wherein the conductive layer contains copper.

7. A semiconductor device comprising:
a first insulator formed above a semiconductor substrate;
a first wiring formed in the first insulator;
a second wiring formed above the first wiring;
a contact plug connecting the first and second wirings;
a second insulator formed around at least one of the second wiring and contact plug and including a recovered layer formed in the vicinity of an interface between the second insulator and the second wiring or contact plug, wherein the recovered layer is treated to make a carbon concentration and/or film density therein being equal to or higher than those in the inside of the second insulator;
a barrier metal interposed between the second insulator and the second wiring or contact plug; and
a third insulator interposed between the barrier metal and the second insulator.

8. The device according to claim 7, wherein the low dielectric constant insulator has a dielectric constant of 2.5 or less.

9. The device according to claim 7, wherein the second insulator contains silicon and at least one of carbon and nitrogen.

10. The device according to claim 7, wherein a surface of the second insulator is smoother than a surface of the low dielectric constant insulator contacting.

11. The device according to claim 7, wherein a rate of resistivity increase of the conductive layer formed in the contact hole with the second insulator is less than 20% compared with the resistivity of the conductive layer without the second insulator.

12. The device according to claim 7, wherein the conductive layer contains copper.

13. The device according to claim 7, further comprising:
a wiring metal diffusion preventing conductive film formed on a surface of the first wiring.

14. The device according to claim 7, further comprising:
a wiring metal diffusion preventing film formed between the first and second insulators, and through which the contact plug is formed.

15. A method for manufacturing a semiconductor device, comprising:
depositing a first insulator above a semiconductor substrate;
forming at least one of a wiring trench and contact hole in the first insulator;
recovering damage introduced to the first insulator in the vicinity of the surface of the wiring trench and/or contact hole;
forming a second insulator on a surface of the wiring trench and/or contact hole;
forming a barrier metal on the second insulator; and
forming a conductive layer in at least one of the wiring trench and contact hole.

16. The method according to claim 15, wherein the low dielectric constant insulator has a dielectric constant of 2.5 or less.

17. The method according to claim 15, wherein the second insulator contains silicon and at least one of carbon and nitrogen.

18. The method according to claim 15, wherein a rate of resistivity increase of the conductive layer formed in the contact hole with the second insulator is less than 20% compared with the resistivity of the conductive layer without the second insulator.

19. The method according to claim 15, wherein the conductive layer contains copper.

20. The method according to claim 15, wherein the first insulator is formed on a wiring metal diffusion preventing insulator, and wherein the wiring metal diffusion preventing insulator at the bottom of the contact hole is removed before the recovering.
